(19) United States
(12) Patent Application Publication
(10) Pub. No.: US 2014/0035597 A1
(43) Pub. Date: Feb. 6, 2014

(54) Vehicle With Inductive Measuring Unit For Detecting Position Of Vehicle Part

(71) Applicant: Casco Schoeller GmbH, Frankfurt am Main (DE)

(72) Inventor: Marek Luszczewski, Bensheim (DE)

(21) Appl. No.: 13/955,100

(22) Filed: Jul. 31, 2013

(30) Foreign Application Priority Data
Jul. 31, 2012 (DE) 102012015035.0

(51) Int. Cl. G01R 27/26

(52) U.S. Cl. CPC G01R 27/2611
USPC 324/654

(57) ABSTRACT

The invention relates to a vehicle with an inductive measuring unit for detecting the distance between a measuring point P₁ on one vehicle part 10 and a measuring point P₂ on another vehicle part 30 that can be moved on a movement plane in relation to the one vehicle part.

The invention relates to a vehicle with an inductive measuring unit for detecting the distance between a measuring point on a vehicle part and a measuring point on another vehicle part that is moveable on a movement plane in relation to the other vehicle part.

To regulate the range of the headlights of a vehicle, for example of a passenger car, devices are known with which the incline of the vehicle with respect to the road, the called nod position, is detected. The nod position of the vehicle changes, for one, during acceleration and braking and, for another, upon loading of the vehicle.

The known devices for detecting the nod position of the vehicle have an inductive measuring unit that determines the distance between a measuring point on one part of the vehicle chassis and a measuring point on a transverse control arm of the vehicle. The transverse control arm of the vehicle is pivoted on a plane that will be referred to hereinafter as the movement plane. In the event of a tilting angle, the measuring point on the transverse control arm moves substantially on a straight line that lies on the movement plane.

The known inductive measuring units for determining the distance between two opposing vehicle parts have an electrical resonant circuit comprising an inductivity (sensor coil) and a capacitance (capacitor). The quality factor (attenuation) of this resonant circuit is determined by the measured distance between the sensor coil and an electrically conductive metallic object (target). In an evaluation unit, the amplitude change of the electrical resonance of the resonant circuit is detected on the basis of the distance between the measuring points.

Preferably, the target forms a flat metallic surface of the respective vehicle part. By contrast, non-ferromagnetic materials, such as plastics, organic materials or most liquids, do not influence the attenuation (quality factor) of the resonant circuit. If the respective vehicle part as such is non-metallic, a metal part can also be arranged on the vehicle part. Since the inductive measuring unit works in a contactless manner, a mechanical coupling is not necessary. As a result, the design complexity is low. In addition, no problems arise upon soiling or freezing.

DE 103 41 485 B4 describes an inductive measuring unit for detecting the position of a vehicle part for the regulation of the range of a headlight.

The known inductive measuring systems have proven themselves in practice. To detect the distance between the measuring points, the sensor coil of the inductive measuring unit is arranged above the transverse control arm on a part of the vehicle chassis such that the measurement plane of the sensor coil and the flat surface of a part of the transverse control arm (target) oppose one another. At a small tilting angle, measurement plane and target are aligned parallel to one another.

In the known inductive measuring systems, the measurement of the maximum distance between the measuring points is determined through the intensity of the electromagnetic field that is produced by the resonant circuit. The magnetic field intensity, in turn, is determined by the size of the sensor coil. However, since the designed space available for the installation of the sensor coil is limited, only relatively small deflections of the transverse control arm can be detected with the known measuring units. The maximum distance between the two measuring points can therefore be no greater than about 35 mm in practice.

In the inductive measuring units of the known devices for detecting the position of vehicle parts, the generally nonlinear relationship between the spacing of the two measuring points and the amplitude of the measurement signal generated by the evaluation unit turns out to be disadvantageous. Particularly, there is a nonlinear relationship when the deflection of the transverse control arm exceeds the measurement range of the inductive measuring unit which, in turn, sets limits for the use of the known measuring systems.

It is the object of the invention to detect, in the limited designed space available in a vehicle, even larger distances between vehicle parts that move in relation to one another with greater precision.

This object is achieved according to the invention with the features of patent claim 1. The subject matter of dependent claims 2 to 9 relates to preferred embodiments of the invention.

It is another object of the invention to provide a method for the linearization of the measurement signal of an inductive measuring unit in order to detect, in a contactless manner, the distance between vehicle parts that can move in relation to one another. This object is achieved according to the invention with the features of independent patent claim 10.

The inductive measuring unit of the vehicle according to the invention has a sensor coil associated with one vehicle part for generating an electromagnetic field, which sensor coil defines a measurement plane on which the measuring point of one vehicle part lies, whereas the surface of an electrically conductive body opposite the measurement plane of the sensor coil defines a reference plane on which the measuring point of the other vehicle part lies.

The sensor coil is to be understood as an inductivity that is part of an electrical resonant circuit of the inductive measuring unit. The sensor inductivity can comprise one or more coils. The only decisive thing is that an electromagnetic field be generated with the sensor coil as part of the electrical resonant circuit.

The electromagnetic field produces eddy currents in the electrically conductive body, so that the quality factor (attenuation) of the electrical resonant circuit is changed. The electrically conductive body can be a part of the vehicle part or a part arranged on the vehicle part.

For the invention, it is not crucial how the inductive measuring unit is designed. The basic principle of the invention lies in the special arrangement of the measurement plane of the sensor coil on the one hand and the reference plane of the electrically conductive body on the other hand. While in the prior art the measurement plane of the sensor coil is arranged at a right angle to the plane on which the moveable vehicle part moves, the invention provides for the arrangement of the movement plane at a non-right angle. The angle enclosed by the movement plane and the movement plane is advantageously between 25 and 65°, preferably between 35 and 55°, especially preferably between 40 and 50°, particularly at 45°. Preferably, the angle enclosed by the reference plane and movement plane also lies within the abovementioned ranges so that measurement plane and reference plane are aligned.

This special arrangement offers the advantage that, even when there is a large distance between the vehicle parts, the distance to be detected by the inductive measuring unit between the measuring points is relatively small, so that a relatively large distance between the vehicle parts can be measured even with a sensor coil of relatively small size. Another substantial advantage is that the inductive measuring unit can be operated in an area in which the relationship between measurement signal and distance is linear or at least approximately linear.

The method according to the invention for the linearization of the measurement signal of an inductive measuring unit provides for the changing of the angle enclosed by the measurement plane of the sensor coil and the movement plane and the detection of the dependence of the measurement signal from the distance between the measuring points in order to detect an angle at which the dependence of the measurement signal from the distance between the measuring points is a linear relationship or at least an approximately linear relationship, i.e., the deviation between the actual relationship and a linear relationship is the smallest (correlation). As a result, it is possible to create a linear relationship solely by means of the arrangement according to the invention of the measurement plane and the movement plane without requiring an elaborate evaluation of the measurement signal.

In the following, a sample embodiment of the invention is described in detail with reference to the drawings.

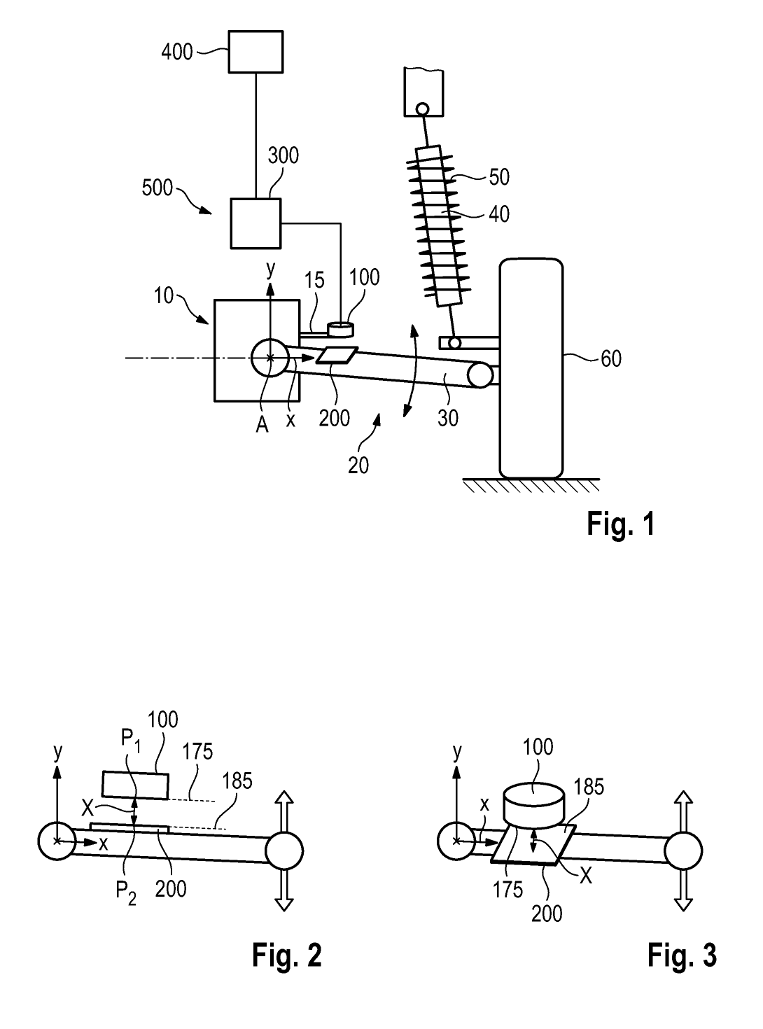

FIG. 1 shows a highly simplified schematic representation of the essential components of a vehicle with an inductive measuring unit for detecting the distance between two vehicle parts that can move with respect to one another, FIG. 2 shows a schematic representation of the arrangement of the sensor coil and the electrically conductive body of an inductive measuring unit according to the prior art,

FIG. 3 shows a schematic representation of the sensor coil and the electrically conductive body in the arrangement according to the invention,

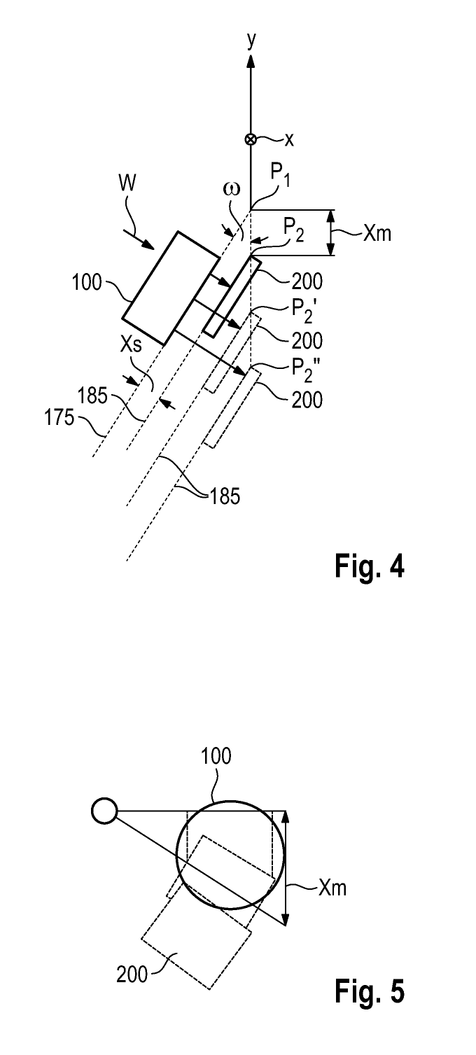

FIG. 4 shows a schematic representation of the trajectory of the sensor coil and the conductive body,

FIG. 5 shows a view of the sensor coil from the direction of the arrow W from FIG. 4,

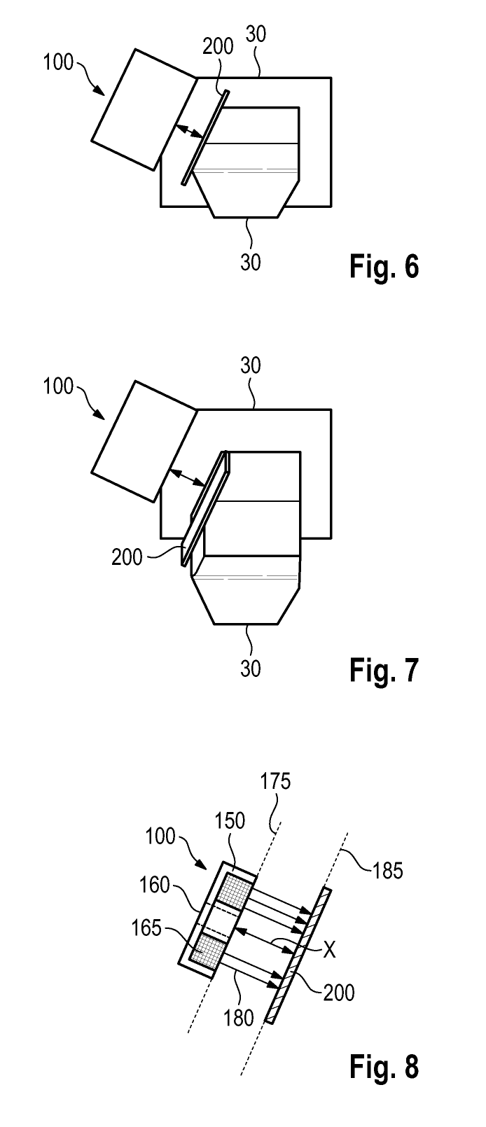

FIG. 6 shows a perspective representation of the sensor coil of the conductive body in a first position of the transverse control arm,

FIG. 7 shows the sensor coil and the conductive body in a second position of the transverse control arm,

FIG. 8 shows a sectional representation of a sample embodiment of the sensor coil,

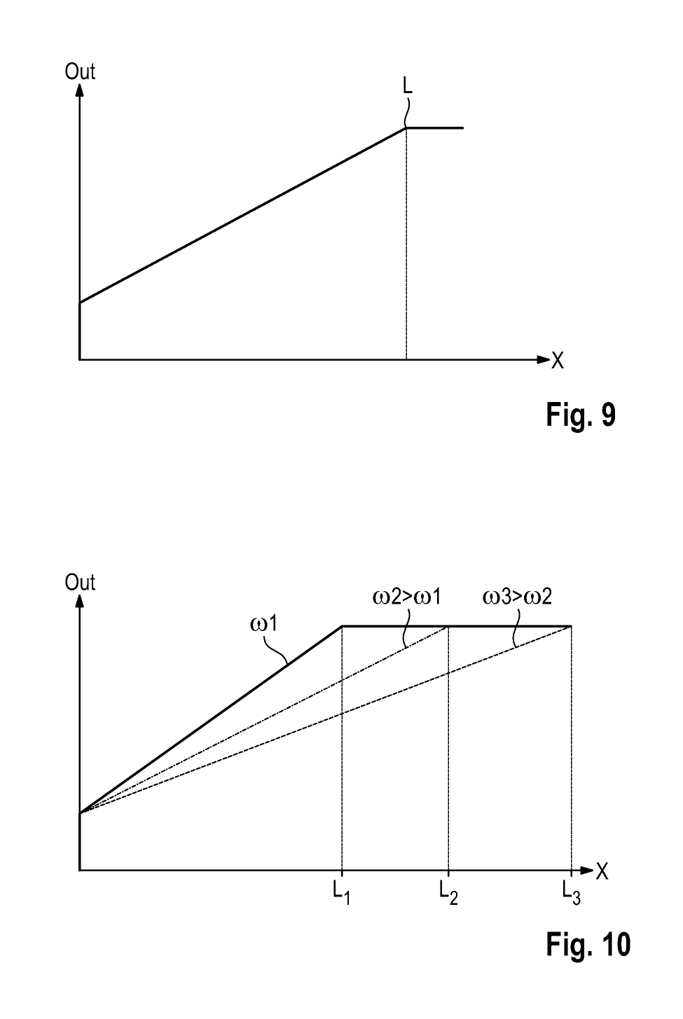

FIG. 9 shows the output signal of the evaluation unit as a function of the distance between the measuring points, and

FIG. 10 shows the output signal of the evaluation unit as a function of the distance between the measuring points for different angles that are enclosed by the measurement plane and the movement plane.

FIG. 1 shows the components of a vehicle that are essential for the invention. The chassis and the suspension of the vehicle are designated with reference symbols 10 and 20. The suspension 20 comprises from and rear transverse control arms made of an electrically conductive, metallic metal, for example steel or aluminum, which are articulated on the chassis 20. For the sake of clarity, FIG. 1 shows only one transverse control arm 30. The transverse control arm 30, unlike the vehicle chassis 10, represents a moveable vehicle part that is articulated in a swiveling manner about an axis A, so that the transverse control arm can move on a plan X, Y, which will be referred to hereinafter as the movement plane. The spring strut belonging to the transverse control arm 30 and the shock absorber as well as the wheel are referred to with reference symbols 40, 50, 60.

The vehicle has an inductive measuring unit 500 whose components are shown only schematically in FIG. 1. The inductive measuring unit can, for example, be the measurement system that is described in DE 103 41 485 B4 and to which reference is expressly made. The measuring unit has a sensor coil 100 that is part of an electrical resonant circuit (not shown in further detail) of the inductive measuring unit. The sensor coil 100 is arranged on a part 15 of the chassis 10 that represents an immoveable vehicle part.

FIG. 8 shows a sample embodiment of the sensor coil 100 of the inductive measuring unit 500. The sensor coil 100 is arranged in a semi-open pot-type core 150 made of ferrite material. The windings 165 of the coil 100 run around the axis 160 of the pot-type core 100. The sensor coil 100 defines a measurement plane 175 that lies on a plane on the surface of the pot-type core on the open side. The magnetic field lines 180 run to the measurement plane 175 at a substantially right angle.

In the present sample embodiment, an electrically conductive body 200 is arranged on the transverse control arm 30 opposite the measurement plane 175 of the sensor coil 100. In the present sample embodiment, the electrically conductive body 200 is a metal plate with a flat surface (target) that represents a reference plane 185. A change in the distance between the measurement plane 175 and the reference plane 185 leads to an attenuation of the electrical resonant circuit. The inductive measuring unit 500 has an evaluation unit 300 that generates an electrical measurement signal that is dependent on the distance X between the measurement plane 175 and the reference plane 185 (FIG. 8).

FIG. 9 shows the dependence of the amplitude of the measurement signal Out on the distance X. As the distance X increases, the measurement signal increases until a threshold value L is exceeded. The threshold value L represents the maximum distance that can be measured with the inductive measuring unit.

FIG. 2 shows the arrangement of the sensor coil 100 and the metallic body 200 according to the prior art. The inductive measuring unit 500 measures the distance between a stationary point P₁ on a part 15 of the chassis 10 and a moveable point P₂ on an electrically conductive body 200 of the transverse control arm 30. For small tilting angles, the two measuring points P₁ and P₂ are on a straight line that lies on the movement plane X, Y of the transverse control arm 30. According to the prior art, the angle enclosed between the measurement plane 175 of the sensor coil 100 and the movement plane X, Y is a right angle. There it is assumed that, for small tilting angles, both the measurement plane 175 and the reference plane 185 run substantially parallel to one another when the distance X between the measuring points P₁ and P₂ changes. According to the prior art, the maximum measured distance is the threshold value L (FIG. 9).

In the following, the arrangement of the sensor coil 100 and the electrically conductive body 200 in the measuring unit 500 according to the invention is described with reference to FIGS. 3 to 7.

FIG. 3 shows a schematic representation of the arrangement of sensor coil 100 and metal body 200. FIGS. 6 and 7 show the arrangement of sensor coil 100 and metal body 200 from another perspective for two different positions of the transverse control arm.

FIGS. 4 and 5 show, from two different perspectives, the trajectory of the transverse control arm during its up-and-down movement on the movement plane.

FIG. 4 shows the position of the measuring point P₁ on the chassis 10 and the different positions of the measuring point P₂, P₂″, P₂′ during the movement of the transverse control arm 30 with the metal plate 200 on the movement plane X, Y. The distance between the measuring points P₁ and P₂ on the chassis 10 and transverse control arm 30 is designated with Xm. For a small tilting angle, the measuring point P₂ on the transverse control arm moves approximately on a straight line that lies on the movement plane of the transverse control arm. In FIG. 4, the movement plane is a plane that is perpendicular to the drawing plane.

In the inductive measuring unit 500 according to the invention, the sensor coil 100 is arranged such that the measurement plane and the movement plane enclose an angle ω that lies between 25 and 65°, preferably between 35 and 55°, especially preferably between 40 and 50°, particularly at 45°. The measurement plane therefore does not run at a right angle but rather transversely to the movement plane. The metal body 200 is arranged on the transverse control arm 30 such that measurement plane 175 and reference plane 185 are parallel at least for small tilting angles. As a result, the reference plane and the movement plane enclose the same angle ω as the measurement plane and the movement plane, at least for small tilting angles.

In the measuring unit 500 according to the invention the distance to be determined between the measuring points P₁ and P₂ is not detected directly, but rather the distance Xs between the measurement plane 175 of the sensor coil 100 and the reference plane 180 of the metal body 200. It is clear from FIG. 4 that, when the point P₂ moves by a segment X of the length Xm, the distance between measurement and reference plane increases by an amount Xs that is smaller than the length of the segment Xm.

Under the assumption that, given a predetermined designed size of the sensor coil 100, only a maximum distance L can be measured (FIG. 9), the detection of a substantially larger deflection of the transverse control arm is possible with the measuring unit 500 according to the invention with the same designed size of the sensor coil than with the prior art. Another advantage is that the measuring unit 500 can be operated in an area in which the dependence between the output signal and the distance X is a linear function. FIG. 10 shows that the threshold value L₁, L₂ and L₃ increases as the angle ω increases.

To linearize the characteristic of the inductive measuring unit 500, the angle ω enclosed by the measurement and movement plane 175, 185 is dimensioned such that a linear relationship results. To do this, the angle is changed, and the dependence of the output signal on the measured distance is detected for different angles. Then the angle is selected at which the dependence of the measurement signal on the distance between the two measuring points P₁ and P₂ is a linear or at least approximately linear relationship. The methods required for this are known to those skilled in the art. For example, the measurement signals can be evaluated using known statistical methods in order to find an optimum angle ω for the respective geometry and the respective material.

The evaluation unit 100 of the inductive measuring unit 500 has a unit for converting the measured distance Xs into the distance Xm to be determined between the measuring point P₁ and P₂. The conversion is done according to the following equation

Xm=Xs/sin(ω),

where Xm is the distance to be determined between the measuring points P₁ and P₂, and Xs is the measured distance between measurement plane 175 and reference plane 180 and the angle ω of the angle enclosed between measurement plane 175 and movement plane X, Y.

Moreover, it is possible to balance out nonlinearities through a special shape of the electrically conductive body. For example, recesses (not shown) can be provided in the metal body in order to reduce the formation of eddy currents. On the other hand, projections can also be provided on the metal body in order to amplify the formation of eddy currents. In this way, the attenuation of the electrical resonant circuit can be changed in a targeted manner.

The distance Xs measured by the inductive measuring unit follows from the relationship of the volume V of the magnetic flow enclosed by the sensor coil and the metal body and the surface Ssens of the sensor coil:

Xs=V/Ssens.

Nonlinearities can be balanced out by changing the volume of the magnetic flow and the surface of the sensor in a certain ratio to one another.

1. A vehicle with
first and second vehicle parts arranged at a distance from one another, of which the second vehicle part can be moved on a movement plane in relation to the first vehicle part, and
an inductive measuring unit configured to detect a distance between a first measuring point on the first vehicle part and a second measuring point on the second vehicle part,
wherein the inductive measuring unit includes a sensor coil associated with the first vehicle part for generating an electromagnetic field, and the second vehicle part includes an electrically conductive body in which the electromagnetic field generates eddy currents, and
wherein the sensor coil defines a measurement plane on which the first measuring point of the first vehicle part lies, and a surface of the electrically conductive body opposite the measurement plane defines a reference plane on which the second measuring point of the second vehicle part lies,
characterized in that
an angle enclosed by the measurement plane and the movement plane is not a right angle.

2. The vehicle as set forth in claim 1, wherein the angle enclosed by the measurement plane and the movement plane is in a range from 25° to 65°.

3. The vehicle as set forth in claim 1, wherein the angle enclosed by the measurement plane and the movement plane is in a range from 35° to 55°.

4. The vehicle as set forth in claim 1, wherein an angle enclosed by the reference plane and the movement plane is in a range from 25° to 65°.

5. The vehicle as set forth in claim 1, wherein an angle enclosed by the reference plane and the movement plane is in a range from 35° to 55°.

6. The vehicle as set forth in claim 1, wherein the sensor coil includes windings running around an axis standing perpendicular on the measurement plane.

7. The vehicle as set forth in claim 1, wherein the sensor coil is arranged in a semi-open pot-type core, the measurement plane being the plane on which a surface of the pot-type core lies on an open side of the semi-open pot-type core.

8. The vehicle as set forth in claim 1, wherein the inductive measuring unit includes an evaluation unit configured to generate an electrical measurement signal correlating to the distance between the measuring points.

9. The vehicle as set forth in claim 1, wherein the first vehicle part is a part of a vehicle chassis and the second vehicle part is a part of a transverse control arm.

10. A method for the linearization of a measurement signal of an inductive measuring unit for the contactless detection of a distance between a first measuring point on one vehicle part and a second measuring point on another vehicle part that moves in relation to the one vehicle part on a movement plane
wherein the inductive measuring unit includes a sensor coil associated with the one vehicle part to generate an electromagnetic field, and the other vehicle part is an electrically conductive body or has includes an electrically conductive body in which the electromagnetic field generates eddy currents, and
wherein the sensor coil defines a measurement plane on which the first measuring point of one vehicle part lies, and the surface of the electrically conductive body opposite the measurement plane defines a reference plane on which the second measuring point of the other vehicle part lies,
method comprising:
changing an angle enclosed by the measurement plane of the sensor coil and the movement plane,
detecting a dependence of the measurement signal on the distance between the measuring points, and
selecting the angle enclosed by the measurement plane of the sensor coil and the movement plane such that the dependence of the measurement signal on the distance between the measuring points is a linear relationship, and
arranging the sensor coil at the selected angle at which the dependence of the measurement signal on the distance between the measuring points is a linear relationship.

11. The vehicle as set forth in claim 1, wherein the angle enclosed by the measurement plane and the movement plane is in a range from 40° to 50°.

12. The vehicle as set forth in claim 1, wherein an angle enclosed by the reference plane and the movement plane is in a range of from 40° to 50°.

13. A vehicle, comprising:
a first vehicle part;
a second vehicle part movable relative to the first vehicle part, the movement being parallel to a movement plane; and
an inductive measuring unit configured to detect relative movement between the first vehicle part and the second vehicle part, the inductive measuring unit including:
a sensor coil attached to the first vehicle part for generating an electromagnetic field, the sensor coil defining a measurement plane oriented such that an acute angle is enclosed by the measurement plane and the movement plane, and
an electrically conductive body included on the second vehicle part, the electrically conductive body including a surface facing the measurement plane, the surface defining a reference plane.

14. The vehicle of claim 13, wherein:
the acute angle enclosed by the measurement plane and the movement plane is in a range from 25° to 65°.

15. The vehicle of claim 14, wherein:
the reference plane is substantially parallel to the measurement plane.

16. The vehicle of claim 13, wherein:
the acute angle enclosed by the measurement plane and the movement plane is in a range from 35° to 55°.

17. The vehicle of claim 16, wherein:
the reference plane is substantially parallel to the measurement plane.

18. The vehicle of claim 13, wherein:
the acute angle enclosed by the measurement plane and the movement plane is in a range from 40° to 50°.

19. The vehicle of claim 18, wherein:
the reference plane is substantially parallel to the measurement plane.

20. The vehicle of claim 13, wherein:
the sensor coil includes windings running around an axis perpendicular to the measurement plane.

21. The vehicle of claim 13, wherein:
the sensor coil is arranged in a semi-open pot-type core, the measurement plane being the plane on which a surface of the pot-type core lies on an open side of the semi-open pot-type core.

22. The vehicle of claim 13, wherein:
the inductive measuring unit includes an evaluation unit configured to generate an electrical measurement signal correlating to a distance between a first point on the first vehicle part and a second point on the second vehicle part.

23. The vehicle of claim 13, wherein:
the first vehicle part is part of a vehicle chassis; and
the second vehicle part is a transverse control arm pivotally attached to the vehicle chassis.
